(19) United States
(12) Patent Application Publication
(10) Pub. No.: US 2017/0040287 A1
(43) Pub. Date: Feb. 9, 2017

(54) ELECTRONIC COMPONENT DEVICE PRODUCTION METHOD AND ELECTRONIC COMPONENT SEALING SHEET

(71) Applicant: NITTO DENKO CORPORATION

(72) Inventors: Goji Shiga, Ibaraki-shi, Osaka (JP); Tsuyoshi Ishizaka, Ibaraki-shi, Osaka (JP); Kosuke Morita, Ibaraki-shi, Osaka (JP); Chie Iino, Ibaraki-shi, Osaka (JP)

(21) Appl. No.: 15/107,203

(22) PCT Filed: Dec. 22, 2014
(86) PCT No.: PCT/JP2014/083930

§ 371 Date: Jun. 22, 2016

(30) Foreign Application Priority Data
Dec. 26, 2013 (JP) 2013-270252

(51) Int. Cl. H01L 23/00; H01L 21/56; H01L 23/29; H01L 23/31; H01L 21/78; B32B 37/18; B32B 7/10; B32B 7/12; B32B 27/08; B32B 27/36; B32B 37/06; C08J 5/18; B29C 65/02

(52) U.S. Cl. CPC H01L 24/96; C08J 5/18; H01L 21/561; H01L 23/293; H01L 23/3107; H01L 21/78; H01L 21/568; B29C 65/02; B32B 7/10; B32B 7/12; B32B 27/08; B32B 27/36; B32B 37/06; B32B 37/182; C08J 2363/02; C08J 2461/06; C08J 2433/10; H01L 2224/12105; H01L 24/13; H01L 2924/0665; B32B 2457/14; B29K 2667/003

(57) ABSTRACT

The electronic component device production method includes a step A of preparing a layered body comprising electronic components immobilized on a support body, a step B of preparing an electronic component sealing sheet, a step C of disposing the electronic component sealing sheet over the electronic components under conditions where the probe tack force of the electronic component sealing sheet is 5 gf or lower according to a probe tack test, a step D of rising the temperature of the electronic component sealing sheet until the probe tack of the electronic component sealing sheet is 10 gf or greater according to the probe tack test to immobilize temporarily the electronic component sealing sheet onto the electronic components, and a step E of embedding the electronic components in the electronic component sealing sheet to form a sealed body comprising the electronic components embedded in the electronic component sealing sheet.

### TECHNICAL FIELD

The present invention relates to a method for manufacturing an electronic component device and a sheet for sealing an electronic component.

### BACKGROUND ART

As a method for manufacturing a semiconductor device, a method has been conventionally known of sealing one or more semiconductor chips fixed to a substrate, etc. with a sealing resin and dicing the sealed body to form a packaged semiconductor device unit. For example, a sealing sheet constituted with a thermosetting resin has been known as the sealing resin (for example, refer to Patent Document 1).

### PRIOR ART DOCUMENT

### Patent Document

Patent Document 1: JP-A-2006-19714

### DISCLOSURE OF THE INVENTION

### Problems to be Solved by the Invention

When manufacturing an electronic component device with the above-described method, it is necessary to arrange a sealing sheet on the electronic components (for example, semiconductor chips) by aligning the sealing sheet to come on the electronic components that are fixed on a support such as a substrate. However, the sealing sheet generally has adherability. Therefore, if the sealing sheet is arranged (placed) on the electronic components in a condition where positional displacement occurs at the time of aligning, the sealing sheet sticks to the electronic components, and the sealing sheet cannot be peeled. As a result, there is a problem that the sealing sheet cannot be realigned. In addition, when the sealing sheet falls off, etc. due to trouble in apparatus, etc., there is a problem in which the sealing sheet sticks to various types of apparatus, causing contamination.

The present invention has been made in consideration of the above-described problems, and an object thereof is to provide a method for manufacturing an electronic component device capable of easily aligning when arranging a sheet for sealing an electronic component on the electronic components that are fixed on a support, and capable of suppressing various types of apparatus from being contaminated even when the sheet for sealing an electronic component falls off, and a sheet for sealing an electronic component that can be used in the method for manufacturing an electronic component device.

### Means for Solving the Problems

The inventors of the present invention have found that the above-described problems can be solved by adopting the following configuration and completed the present invention.

The method for manufacturing an electronic component device according to the present invention is characterized to include a step A of preparing a laminate in which electronic components are fixed on a support, a step B of preparing a sheet for sealing an electronic component, a step C of arranging the sheet for sealing an electronic component on the electronic components under a condition in which the probe tack force of the sheet for sealing an electronic component in a probe tack test is 5 gf or less, a step D of increasing a temperature of the sheet for sealing an electronic component in a state where the sheet for sealing an electronic component is arranged on the electronic components until the probe tack force of the sheet for sealing an electronic component in a probe tack test becomes 10 gf or more and temporarily fixing the sheet for sealing an electronic component to the electronic components, and a step E of embedding the electronic components in the sheet for sealing an electronic component to form a sealed body in which the electronic components are embedded in the sheet for sealing an electronic component.

According to the method for manufacturing an electronic component device according to the present invention, the probe tack force of the sheet for sealing an electronic component in a probe tack test is 5 gf or less and there is little adherability in the step (Step C) of arranging the sheet for sealing an electronic component on the electronic components. Therefore, the sheet for sealing an electronic component can be easily rearranged even when the sheet for sealing an electronic component is arranged (placed) in a condition where positional displacement occurs in a step (Step C) of arranging the sheet for sealing an electronic component on the electronic components. Because the sheet for sealing an electronic component has little adherability in the step (Step C) of arranging the sheet for sealing an electronic component on the electronic components, various types of apparatus can be suppressed from being contaminated even when the sheet for sealing an electronic component falls off, etc. due to trouble in apparatus, etc.

Further, a temperature of the sheet for sealing an electronic component in a state where the sheet for sealing an electronic component is arranged on the electronic components is increased until the probe tack force of the sheet for sealing an electronic component in a probe tack test becomes 10 gf or more, and the sheet for sealing an electronic component is temporarily fixed to the electronic components (Step D). Therefore, the adherability can be exhibited to fix (temporarily fix) the sheet for sealing an electronic component to the electronic components after the alignment is completed.

After the step D, the electronic components are embedded in the sheet for sealing an electronic component to forma sealed body in which the electronic components are embedded in the sheet for sealing an electronic component (Step E). Because no positional displacement occurs between the sheet for sealing an electronic component and the electronic components, the yield of the electronic component device manufactured from the sealed body becomes satisfactory.

In the above-described configuration, the probe tack force of the sheet for sealing an electronic component in a probe tack test is preferably 5 gf or less at 25° C., and 10 gf or more at 40° C.

If the probe tack force of the sheet for sealing an electronic component in a probe tack test is 5 gf or less at 25° C. and 10 gf or more at 40° C., it is possible to make the sheet for sealing an electronic component exhibit little adherability at a normal temperature of about 25° C. or lower (for example, about 15° C. to 25° C.) without cooling the sheet for sealing an electronic component to a low temperature (for example, about −10° C. to 5° C.). In addition, the temperature may be increased to about 40° C. or higher to make the sheet for sealing an electronic component exhibit adherability. Therefore, the steps C and D can be easily performed.

In the above-described configuration, the step C is preferably a step of arranging the sheet for sealing an electronic component on the electronic components at 25° C. or lower, and the step D is preferably a step of increasing a temperature of the sheet for sealing an electronic component to 40° C. or higher and temporarily fixing the sheet for sealing an electronic component to the electronic components.

If the step C is a step of arranging the sheet for sealing an electronic component on the electronic components at 25° C. or lower, the sheet for sealing an electronic component does not stick to the electronic components at the stage of the step C. Therefore, the alignment can be easily performed.

If the step D is a step of increasing a temperature of the sheet for sealing an electronic component to 40° C. or higher and temporarily fixing the sheet for sealing an electronic component to the electronic components, the sheet for sealing an electronic component exhibits adherability and sticks to the electronic components as a result of the step D. Therefore, the fixing (temporary fixing) can be securely performed.

The sheet for sealing an electronic component according to the present invention is characterized to have a probe tack force in a probe tack test of 5 gf or less at 25° C. and 10 gf or more at 40° C.

According to the above-described configuration, because the probe tack force in a probe tack test is 5 gf or less at 25° C. and 10 gf or more at 40° C., it is possible to make the sheet for sealing an electronic component exhibit little adherability at a normal temperature of about 25° C. or lower (for example, about 15° C. to 25° C.) without cooling the sheet for sealing an electronic component to a low temperature (for example, about −10° C. to 5° C.). In addition, the temperature may be increased to about 40° C. or higher to make the sheet for sealing an electronic component exhibit adherability. Therefore, the handleability of the sheet for sealing an electronic component is excellent. Particularly, the method for manufacturing an electronic component device can be suitably used.

### Effect of the Invention

The present invention can provide a method for manufacturing an electronic component device capable of easily aligning when arranging a sheet for sealing an electronic component on the electronic components that are fixed on a support, and capable of suppressing various types of apparatus from being contaminated even when the sheet for sealing an electronic component falls off, and a sheet for sealing an electronic component that can be used in the method for manufacturing an electronic component device.

### BRIEF DESCRIPTION OF THE DRAWINGS

FIG. 1(a) is a schematic cross section for explaining the method for manufacturing a semiconductor device according to the present embodiment, and FIG. 1(b) is a plane view of the same.

FIG. 2(a) is a schematic cross section for explaining the method for manufacturing a semiconductor device according to the present embodiment, and FIG. 2(b) is a plane view of the same.

FIG. 3(a) is a schematic cross section for explaining the method for manufacturing a semiconductor device according to the present embodiment, and FIG. 3(b) is a plane view of the same.

FIG. 4 is a schematic plane view showing a state of the sheet for sealing an electronic component being arranged in a condition where positional displacement occurs.

FIG. 5 is a schematic cross section for explaining the method for manufacturing a semiconductor device according to the present embodiment.

FIG. 6 is a schematic cross section for explaining the method for manufacturing a semiconductor device according to the present embodiment.

FIG. 7 is a schematic cross section for explaining the method for manufacturing a semiconductor device according to the present embodiment.

FIG. 8 is a schematic cross section for explaining the method for manufacturing a semiconductor device according to the present embodiment.

FIG. 9 is a schematic cross section for explaining the method for manufacturing a semiconductor device according to the present embodiment.

FIG. 10 is a schematic cross section for explaining the method for manufacturing a semiconductor device according to the present embodiment.

### MODE FOR CARRYING OUT THE INVENTION

The embodiments of the present invention will be explained below by referring the drawings. However, the present invention is not limited to only these embodiments.

The method for manufacturing an electronic component device according to the present embodiment includes at least a step A of preparing a laminate in which semiconductor chips are fixed on a temporary fixing material, a step B of preparing a sheet for sealing an electronic component having a probe tack force in a probe tack test of 5 gf or less at 25° C. and 10 gf or more at 40° C., a step C of arranging the sheet for sealing an electronic component on the semiconductor chips at 25° C. or lower, a step D of increasing a temperature of the sheet for sealing an electronic component in a state where the sheet for sealing an electronic component is arranged on the semiconductor chips to 40° C. or higher and temporarily fixing the sheet for sealing an electronic component to the semiconductor chips, and a step E of embedding the semiconductor chips in the sheet for sealing an electronic component to form a sealed body in which the semiconductor chips are embedded in the sheet for sealing an electronic component.

The case will be explained in the present embodiment in which “the laminate in which the electronic components are fixed on a support” of the present invention is “a laminate in which the semiconductor chips are temporarily fixed to a temporary fixing material”. The present embodiment is what is called a method for manufacturing an electronic component device referred to as fan-out wafer level packaging (WLP).

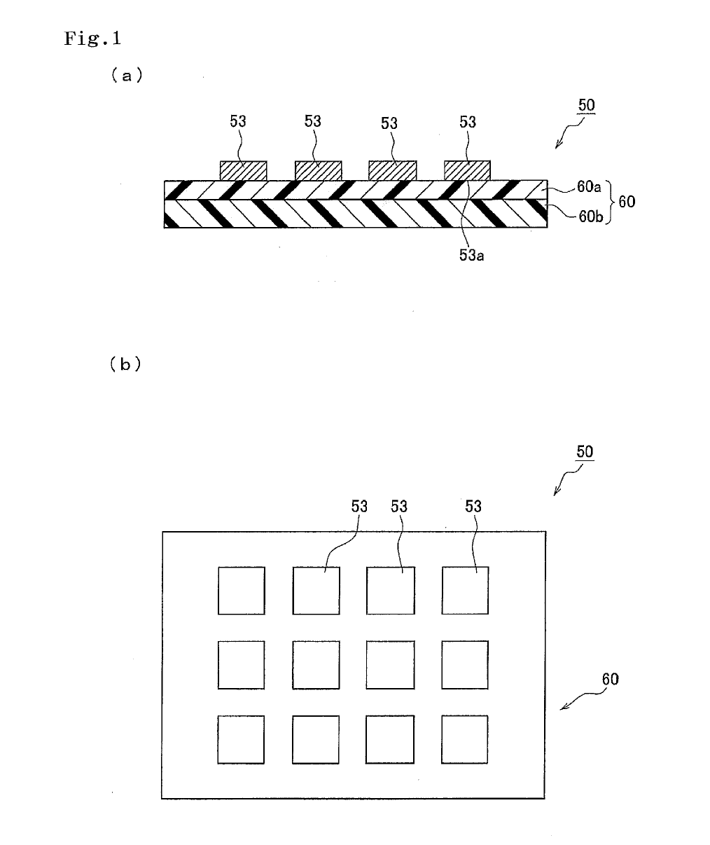

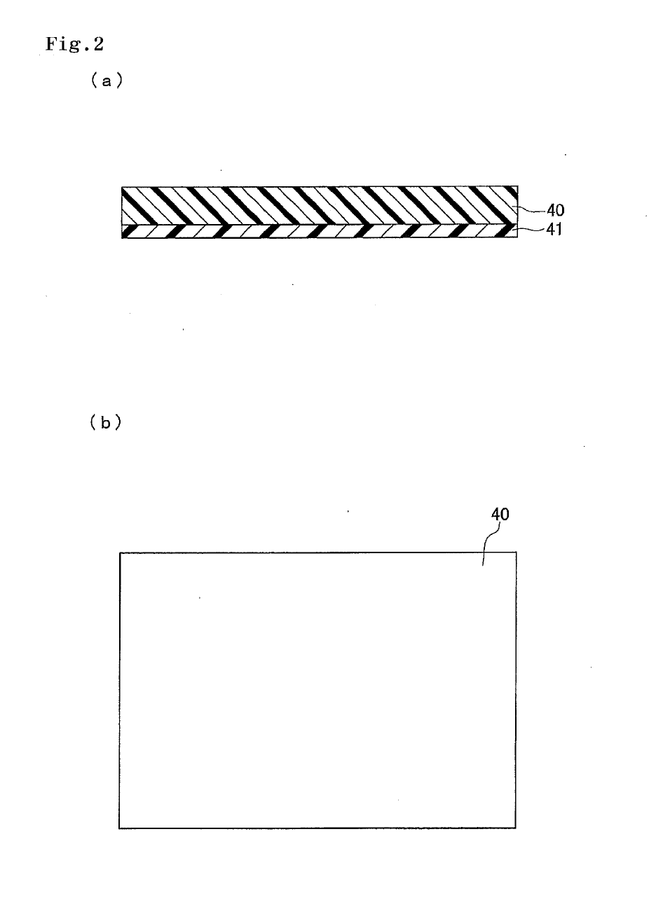

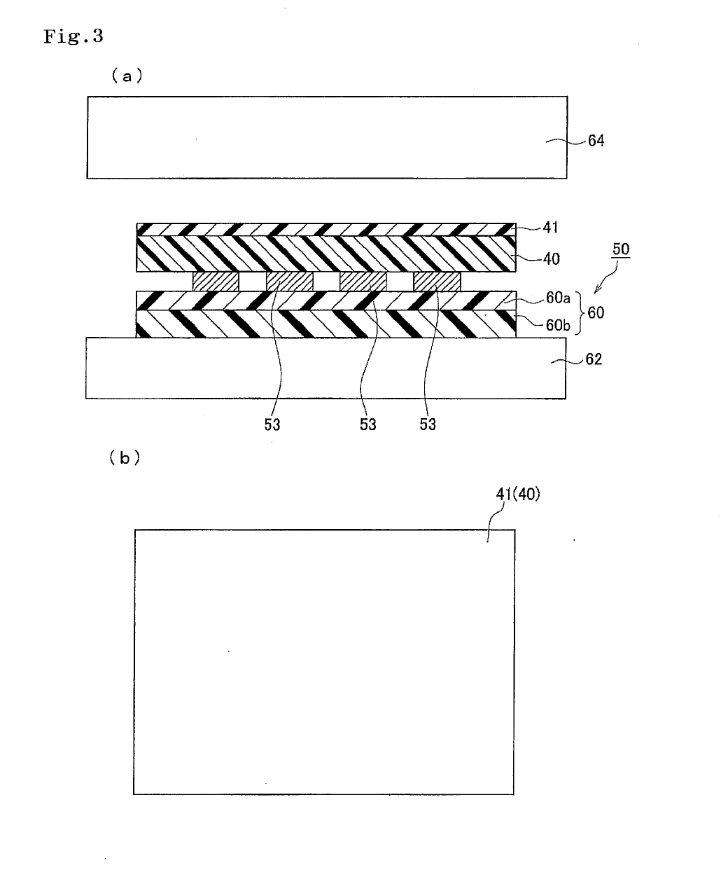

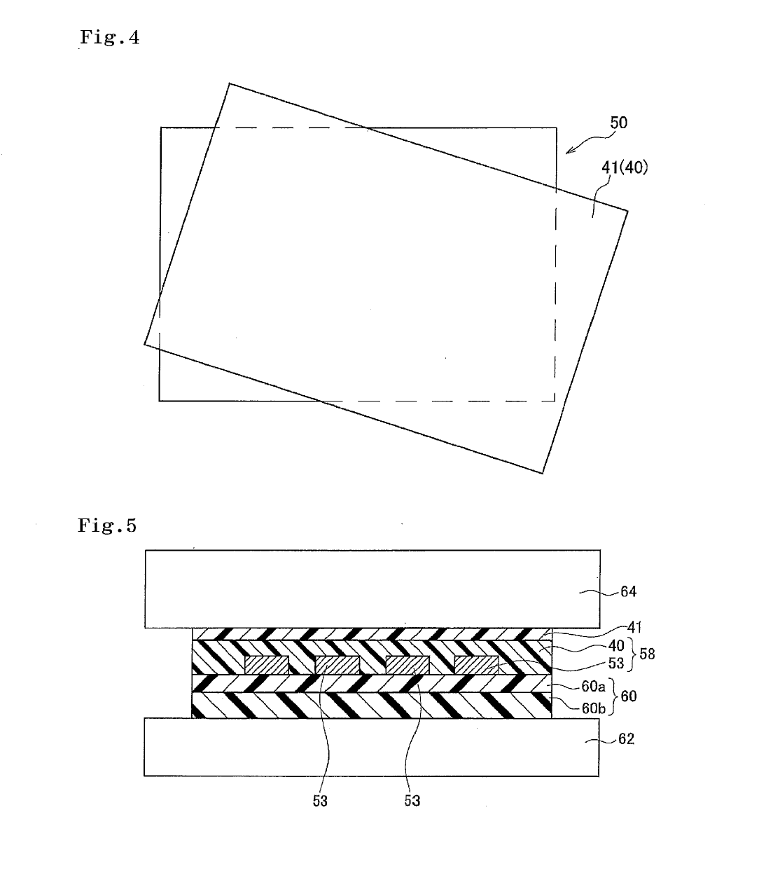

FIG. 1(a) is a schematic cross section for explaining the method for manufacturing a semiconductor device according to the present embodiment, and FIG. 1(b) is a plane view thereof. FIG. 2(a) is a schematic cross section for explaining the method for manufacturing a semiconductor device according to the present embodiment, and FIG. 2(b) is a plane view thereof. FIG. 3(a) is a schematic cross section for explaining the method for manufacturing a semiconductor device according to the present embodiment, and FIG. 3(b) is a plane view thereof. FIG. 4 is a schematic plane view showing a state of the sheet for sealing an electronic component being arranged in a condition where positional displacement occurs. FIGS. 5 to 10 are schematic cross sections for explaining the method for manufacturing a semiconductor device according to the present embodiment. An upper heating plate and a lower heating plate are omitted in FIGS. 3(b) and 4 for convenience of explanation.

### [Step of Preparing Laminate]

In the method for manufacturing a semiconductor device according to the present embodiment, a laminate 50 is first prepared in which semiconductor chips 53 are temporarily fixed on a temporary fixing material 60 as shown in FIGS. 1(a) and 1(b) (Step A). In the present embodiment, the temporary fixing material 60 corresponds to “the support” of the present invention. The semiconductor chips 53 correspond to “the electronic components” of the present invention. For example, the laminate 50 can be obtained as below.

### <Step of Preparing Temporary Fixing Material>

In the step of preparing a temporary fixing material, the temporary fixing material 60 is prepared in which a thermally expandable pressure-sensitive adhesive layer 60a is laminated on a supporting base 60b (refer to FIG. 1(a)). A radiation curing type pressure-sensitive adhesive layer can be also used instead of the thermally expandable pressure sensitive adhesive layer. The temporary fixing material 60 with a thermally expandable pressure-sensitive adhesive layer will be explained in the present embodiment.

### (Thermally Expandable Pressure-Sensitive Adhesive Layer)

The thermally expandable pressure-sensitive adhesive layer 60a can be formed with a polymer component and a pressure-sensitive adhesive composition containing a foaming agent. An acrylic polymer (may be referred to as “acrylic polymer A”) can be suitably used as the polymer component (especially, as a base polymer). An example of the acrylic polymer A is an acrylic polymer having (meth)acrylic ester as a main monomer component. Examples of (meth)acrylic ester include (meth)acrylic alkyl ester (straight-chain or branched-chain alkyl ester having an alkyl group of 1 to 30 carbon atoms, especially 4 to 18 carbon atoms, such as methyl ester, ethyl ester, propyl ester, isopropyl ester, butyl ester, isobutyl ester, sec-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester, and eicosyl ester) and (meth)acrylic cycloalkyl ester (such as cyclopentyl ester and cyclohexyl ester). These (meth)acrylic esters may be used either alone or in combination of two or more thereof.

The acrylic polymer A may contain a unit corresponding to other monomer components copolymerizable with the (meth)acrylic ester as necessary to modify its cohesive strength, heat resistance, cross-linking properties, etc. Example of these monomer components include a carboxyl group-containing monomer such as acrylic acid, methacrylic acid, itaconic acid, maleic acid, fumaric acid, crotonic acid, and carboxyethylacrylate; an acid anhydride group-containing monomer such as maleic anhydride and itaconic anhydride; a hydroxyl group-containing monomer such as hydroxyethyl (meth)acrylate, hydroxypropyl (math)acrylate, and hydroxybutyl (meth)acrylate; an (N-substituted or unsubstituted) amide-based monomer such as (meth)acrylamide, N,N-dimethyl (meth)acrylamide, N-butyl (meth)acrylamide, N-methylol (meth)acrylamide, and N-methylolpropane (meth)acrylamide; a vinyl ester-based monomer such as vinylacetate and vinylpropionate; a styrene-based monomer such as styrene and α-methylstyrene; a vinylether-based monomer such as vinylmethylether and vinylethylether; a cyanoacrylate-based monomer such as acrylonitrile and methacrylonitrile; an epoxy group-containing acrylic monomer such as glycidyl (meth)acrylate; olefin or a diene-based monomer such as ethylene, propylene, isoprene, butadiene, and isobutylene; a (substituted or unsubstituted) amino group-containing monomer such as aminoethyl (meth)acrylate, N,N-dimethylaminoethyl (meth)acrylate, and t-butylaminoethyl (meth)acrylate; an alkoxyalkyl (meth)acrylate-based monomer such as methoxyethyl(meth)acrylate and ethoxyethyl (meth)acrylate; a monomer having a nitrogen atom-containing ring such as N-vinylpyrrolidone, N-methylvinylpyrrolidone, N-vinylpyridine, N-vinylpiperidone, N-vinylpyrimidine, N-vinylpiperazine, N-vinylpyrazine, N-vinylpyrrole, N-vinylimidazole, N-vinyloxazole, N-vinylmorpholine, and N-vinylcaprolactam; N-vinylcarboxamide; a sulfonic acid group-containing monomer such as styrenesulfonic acid, allylsulfonic acid, (meth)acrylamide propanesulfonic acid, and sulfopropyl (meth)acrylate; a phosphate group-containing monomer such as 2-hydroxyethylacryloylphosphate; a maleimide-based monomer such as N-cyclohexylmaleimide, N-isopropylmaleimide, N-laurylmaleimide, and N-phenylmaleimide; an itaconimide-based monomer such as N-methylitaconimide, N-ethylitaconimide, N-butylitaconimide, N-octylitaconimide, N-2-ethylhexylitaconimide, N-cyclohexylitaconimide, and N-laurylitaconimide; a succinimide-based monomer such as N-(meth)acryloyloxymethylene succinimide, N-(meth)acryloyl-6-oxyhexamethylene succinimide, and N-(meth)acryloyl-8-oxyoctamethylene succinimide; a glycol-based acrylic ester monomer such as polyethyleneglycol (meth)acrylate and polypropyleneglycol (meth)acrylate; a monomer having an oxygen atom-containing heterocyclic ring such as tetrahydrofurfuryl (meth)acrylate; an acrylic ester-based monomer containing a fluorine atom such as fluorine-based (meth)acrylate; an acrylic ester-based monomer containing a silicon atom such as silicone-based (meth)acrylate; and a polyfunctional monomer such as hexanediol (meth)acrylate, (poly)ethyleneglycol di(meth)acrylate, (poly)propyleneglycol di(meth)acrylate, neopentylglycol di(meth)acrylate, pentaerythritol di(meth)acrylate, trimethylolpropane tri(meth)acrylate, pentaerythritol tri(meth)acrylate, dipentaerythriol hexa(meth)acrylate, epoxyacrylate, polyesteracrylate, urethaneacrylate, divinylbenzene, butyl di(meth)acrylate, and hexyl di(meth)acrylate.

A single monomer or a mixture of two or more types of monomers is polymerized to obtain the acrylic polymer A. The polymerization can be performed with any of the methods such as solution polymerization (such as radical polymerization, anion polymerization, and cation polymerization), emulsion polymerization, bulk polymerization, suspension polymerization, and photopolymerization (such as ultraviolet (UV) polymerization).

The weight average molecular weight of the acrylic polymer A is not particularly limited; however, the weight average molecular weight is preferably 350,000 to 1,000,000 and more preferably about 450,000 to 800,000.

An external cross-linking agent can be appropriately used in the thermally expandable pressure-sensitive adhesive to adjust its adhesive strength. A specific example of the method of external cross-linking is a method of adding a cross-linking agent such as a polyisocyanate compound, an epoxy compound, an aziridine compound, and a melamine-based cross-linking agent for reaction. When the external cross-linking agent is used, the amount to be used is appropriately determined according to the balance between the agent and the base polymer needed to be cross-linked, and even more, according to the use as a pressure-sensitive adhesive. The amount of the external cross-linking agent used is generally 20 parts by weight or less (preferably, 0.1 parts by weight to 10 parts by weight) relative to 100 parts by weight of the base polymer.

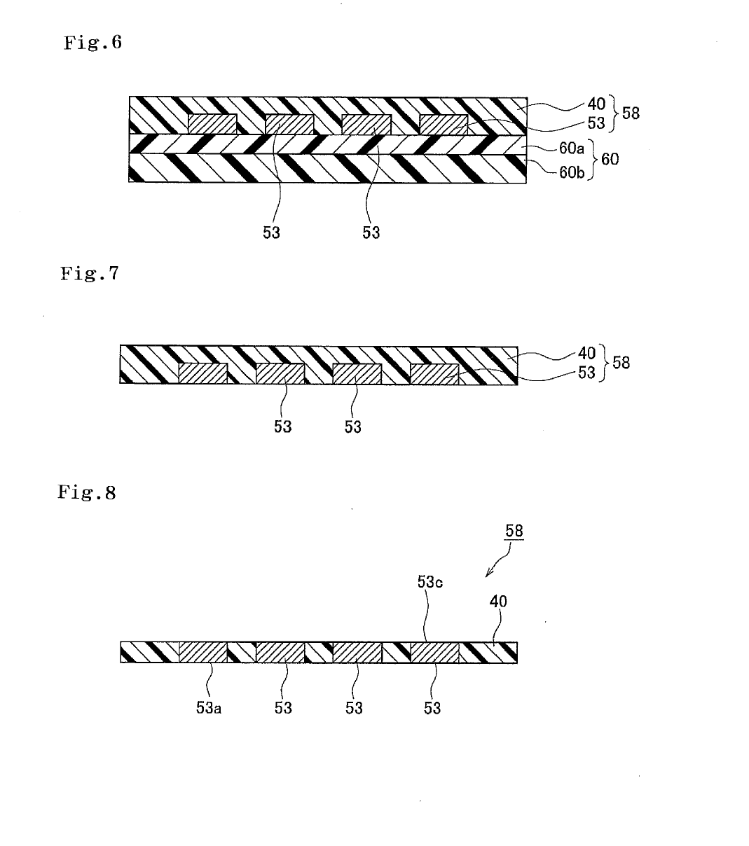

The thermally expandable pressure-sensitive adhesive layer 60a contains a foaming agent so that thermal expansibility can be given to the layer 60a as described above. Therefore, the temporary fixing material 60 is at least partially heated at an arbitrary time while the sealed body 58 is formed on the thermally expandable pressure-sensitive adhesive layer 60a of the temporary fixing material 60 (refer to FIG. 6) to foam and/or expand the foaming agent partially contained in the heated thermally expandable pressure-sensitive adhesive layer 60a. The foaming and/or expansion causes the thermally expandable pressure-sensitive adhesive layer 60a to at least partially expand, which allows the pressure-sensitive adhesive surface (interface between the layer 60a and the sealed body 58) corresponding to the expanding part to deform unevenly, and the adhesion area of the thermally expandable pressure-sensitive adhesive layer 60a to the sealed body 58 decreases. Accordingly, the adhering strength between the thermally expandable pressure-sensitive adhesive layer 60a and the sealed body 58 decreases to peel the sealed body 58 from the temporary fixing material 60 (refer to FIG. 7).

### (Foaming Agent)

The foaming agent used in the thermally expandable pressure-sensitive adhesive layer 60a is not particularly limited, and the foaming agent can be appropriately selected from the known foaming agents. The foaming agent may be used either alone or in combination of two or more thereof. Thermally expandable microspheres can be suitably used as the foaming agent.

### (Thermally Expandable Microspheres)

The thermally expandable microspheres are not particularly limited, and they can be appropriately selected from the known thermally expandable microspheres (various types of inorganic thermally expandable microspheres, organic thermally expandable microspheres). A microencapsulated foaming agent can be suitably used as the thermally expandable microspheres from viewpoints of easy mixing operation, etc. An example of these thermally expandable microspheres includes microspheres in which a substance that gasifies to expand easily by heating such as isobutane, propane, and pentane is encapsulated in an elastic capsule. The capsule is often formed with a thermally fusible substance or a substance that is destroyed by thermal expansion. Examples of the substance forming the capsule include a vinylidene chloride-acrylonitrile copolymer, polyvinyl alcohol, polybutylbutyral, polymethyl methacrylate, polyacrylonitrile, polyvinylidene chloride, and polysulfone.

The thermally expandable microspheres can be manufactured with a traditional method such as a coacervation method and an interface polymerization method. Examples of the thermally expandable microspheres include commercially available products such as trade name “Matsumoto Microsphere” series (for example, trade names “Matsumoto Microsphere F30”, “Matsumoto Microsphere F301D”, “Matsumoto Microsphere F50D”, “Matsumoto Microsphere F501D”, “Matsumoto Microsphere F80SD”, “Matsumoto Microsphere F80VSD”, etc.) manufactured by Matsumoto Yushi-Seiyaku Co., Ltd.; and trade names “051DU”, “053DU”, “551DU”, “551-20DU”, “551-80DU”, etc. manufactured by Expancel Inc.

When the thermally expandable microspheres are used as the foaming agent, the particle size (average particle size) of the thermally expandable microspheres can be appropriately selected according to the thickness of the thermally expandable pressure-sensitive adhesive layer. The average particle size of the thermally expandable microspheres can be selected from the range of, for example, 100 μm or less (preferably 80 μm or less, more preferably 1 μm to 50 μm, and especially preferably 1 μm to 30 μm). The particle size of the thermally expandable microspheres may be adjusted in a production process of the thermally expandable microspheres or with a method such as classifying after the production. The particle size of the thermally expandable microsphere is preferably uniform.

### (Other Foaming Agents)

In the present embodiment, foaming agents other than the thermally expandable microspheres can be also used. Various types of foaming agents such as various types of inorganic foaming agents and organic foaming agents can be appropriately selected and used as the foaming agent. Typical examples of the inorganic foaming agent include ammonium carbonate, ammonium bicarbonate, sodium bicarbonate, ammonium nitride, sodium borohydride, and various types of azide.

Typical examples of the organic foaming agent include water; a chlorofluoroalkane-based compound such trichloromonofluoromethane and dichloromonofluoromethane; an azo-based compound such as azobisisobutyronitrile, azodicarbonamide, and barium azodicarboxylate; a hydrazine-based compound such as paratoluenesulfonylhydrazide, diphenylsulfone-3,3′-disulfonylhydrazide, 4,4′-oxybis(benzenesulfonylhydrazide), and allylbis(sulfonylhydrazide); a semicarbazide-based compound such as p-toluylenesulfonylsemicarbazide, and 4,4′-oxybis(benzenesulfonylsemicarbazide; a triazole-based compound such as 5-morpholil-1,2,3,4-thiatriazole; and an N-nitriso-based compound such as N,N′-dinitrosopentamethyleneteroramine and N,N′-dimethyl-dinitrosoterephthalamide.

In the present embodiment, a foaming agent is preferable that is strong enough not to rupture until the volume expansion coefficient becomes 5 times or more, preferably 7 times or more, and especially preferably 10 times or more in order to reduce the adhering strength of the thermally expandable pressure-sensitive adhesive layer effectively and stably by the heating treatment.

The compounding amount of the foaming agent (such as thermally expandable microspheres) can be appropriately set according to the thermal expansion ratio, the reducing property of the adhering strength, etc. of the thermally expandable pressure-sensitive adhesive layer; however, the compounding amount is generally 1 part by weight to 150 parts by weight (preferably 10 parts by weight to 130 parts by weight and more preferably 25 parts by weight to 100 parts by weight) relative to 100 parts by weight of the base polymer forming the thermally expandable pressure-sensitive adhesive layer.

In the present embodiment, the foaming agent can be suitably used having the foaming initiation temperature (thermal expansion initiation temperature) (T₀) of 80° C. to 210° C., and preferably 90° C. to 200° C. (more preferably 95° C. to 200° C. and especially preferably 100° C. to 170° C.). If the foaming initiation temperature of the foaming agent is lower than 80° C., the foaming agent may be foamed due to heat during the production or use of the sealed body, and the handleability and the productivity deteriorate. On the other hand, when the foaming initiation temperature of the foaming agent exceeds 210° C., excess heat resistance is required in the support and the sealing sheet 40 and it is not preferable in terms of the handleability, the productivity, and the cost. The foaming initiation temperature (T₀) of the foaming agent corresponds to the foaming initiation temperature (T₀) of the thermally expandable pressure-sensitive adhesive layer.

The method for foaming the foaming gent (method for thermally expanding the thermally expandable pressure-sensitive adhesive layer) can be appropriately selected and adopted from the known method of heat foaming.

In the present embodiment, the modulus at 23° C. to 150° C. of the thermally expandable pressure-sensitive adhesive layer without the foaming agent is preferably 5×10⁴ Pa to 1×10⁶ Pa, more preferably 5×10⁴ Pa to 8×10⁵ Pa, and especially preferably 5×10⁴ Pa to 5×10⁵ Pa from a viewpoint of the balance between the moderate adhering strength before the heating treatment and the reducing property of the adhering strength after the heating treatment. If the modulus (temperature: 23° C. to 150° C.) of the thermally expandable pressure-sensitive adhesive layer without the foaming agent is less than 5×10⁴ Pa, the thermally expandability deteriorates, and the peeling property may deteriorate. When the modulus (temperature: 23° C. to 150° C.) of the thermally expandable pressure-sensitive adhesive layer without the foaming agent is larger than 1×10⁶ Pa, the initial adhesion may deteriorate.

The thermally expandable pressure-sensitive adhesive layer without the foaming agent corresponds to the pressure-sensitive adhesive layer formed with a pressure-sensitive adhesive (not containing the foaming agent). Therefore, the modulus of the thermally expandable pressure-sensitive adhesive layer without the foaming agent can be measured using a pressure-sensitive adhesive (not containing the foaming agent). The thermally expandable pressure-sensitive adhesive layer can be formed with a pressure-sensitive adhesive capable of forming a pressure-sensitive adhesive layer having the modulus at 23° C. to 150° C. of 5×10⁴ Pa to 1×10⁶ Pa and a thermally expandable pressure-sensitive adhesive containing the foaming agent.

The thermally expandable pressure-sensitive adhesive layer without the foaming agent added (pressure-sensitive adhesive layer formed with the pressure-sensitive adhesive without the foaming agent) (sample) is produced, and the modulus of the thermally expandable pressure-sensitive adhesive layer without the foaming agent is measured using a dynamic viscoelasticity measurement apparatus “ARES” manufactured by Rheometric Scientific, Inc. under the following conditions: a sample thickness of about 1.5 mm, a parallel plate of φ7.9 mm, a shear mode, a frequency of 1 Hz, a rising temperature speed of 5° C./min, strain of 0.1% (23° C.) and 0.3% (150° C.). The measured values are a shear storage modulus G′ obtained at 23° C. and 150° C.

The types of the base polymer of the pressure-sensitive adhesive, the cross-linking agent, the dopants, etc. can be adjusted to control the modulus of the thermally expandable pressure-sensitive adhesive layer.

The thickness of the thermally expandable pressure-sensitive adhesive layer is not particularly limited, and the thickness can be appropriately selected according to the decreasing property of the adhering strength, etc. For example, the thickness is about 5 μm to 300 μm (preferably 20 μm to 150 μm). However, when the thermally expandable microspheres are used as the foaming agent, the thickness of the thermally expandable pressure-sensitive adhesive layer is preferably larger than the maximum particle size of the thermally expandable microsphere contained. If the thickness of the thermally expandable pressure-sensitive adhesive layer is too small, the surface flatness is lost due to the unevenness of the thermally expandable microspheres, and the adhesion before heating (not foamed) deteriorates. In addition, the degree of deformation of the thermally expandable pressure-sensitive adhesive layer caused by the heating treatment is small, and it becomes difficult for the adhering strength to decrease smoothly. On the other hand, if the thickness of the thermally expandable pressure-sensitive adhesive layer is too large, cohesion failure easily occurs in the thermally expandable pressure-sensitive adhesive layer after the expansion or the foaming due to the heating treatment, and adhesive residue may be generated in the sealed body 58.

The thermally expandable pressure-sensitive adhesive layer may be a single layer or a multiple layer having two or more layers.

In the present embodiment, the thermally expandable pressure-sensitive adhesive layer may contain various kinds of dopants (e.g. colorant, thickener, extender, filler, tackifier, plasticizer, anti-aging agent, antioxidant, surfactant, cross-linking agent, etc.)

### (Supporting Base)

The supporting base 60b is a thin plate-like member becoming a base material for strength of the temporary fixing material 60. The handleability, heat resistance, etc. may be considered to appropriately select the material of the supporting base 60b. Examples thereof include a metal material such as stainless steel (SUS); plastic materials such as polyimide, polyamideimide, polyetheretherketone, and polyethersulfone; glass; and a silicon wafer. Among these, a stainless steel (SUS) plate is preferable from viewpoints of its heat resistance, strength, and recyclability.

The desired strength and the handleability are considered to appropriately select the thickness of the supporting base 60b. The thickness is preferably 100 μm to 5,000 μm and more preferably 300 μm to 2,000 μm.

### (Method of Forming Temporary Fixing Material)

The thermally expandable pressure-sensitive adhesive layer 60a is formed on the supporting base 60b to obtain the temporary fixing material 60. For example, a pressure-sensitive adhesive, a foaming agent (such as thermally expandable microspheres), and a solvent, other dopants, etc. as necessary are mixed together to form the thermally expandable pressure-sensitive adhesive layer with a traditional method of forming a mixture into a sheet-like layer. Specific examples for forming the thermally expandable pressure-sensitive adhesive layer include a method of applying a mixture containing a pressure-sensitive adhesive, a foaming agent (such as thermally expandable microspheres), and a solvent and other dopants as necessary onto the supporting base 60b and a method of applying the mixture onto an appropriate separator (such as release paper) to form the thermally expandable pressure-sensitive adhesive layer and transferring (transferring and pasting) the layer onto the supporting base 60b.

### (Method of Thermally Expanding Thermally Expandable Pressure-Sensitive Adhesive Layer)

In the present embodiment, the thermally expandable pressure-sensitive adhesive layer can be thermally expanded by heating. For example, the method of heat treatment can be performed using an appropriate heating means such as a hot plate, a hot air dryer, a near infrared lamp, and an air dryer. The heating temperature during the heat treatment may be the foaming initiation temperature (thermal expansion initiation temperature) or more of the foaming agent (such as thermally expandable microspheres) in the thermally expandable pressure-sensitive adhesive layer, and the conditions of the heat treatment can be appropriately set according to the decreasing property of the adhesion area due to the types of the foaming agent (such as thermally expandable microspheres), the heat resistance of the sealed body containing the supporting base and the semiconductor chip, the heating method (heat capacity, heating means, etc.) The general conditions of the heat treatment are as follows: a temperature of 100° C. to 250° C. for 1 second to 90 seconds (in case of using a hot plate, etc.) or for 5 minutes to 15 minutes (in case of using a hot air dryer, etc.). The heat treatment can be performed in appropriate stages depending on the use. An infrared lamp or heating water may be used as a heat source during the heat treatment.

### (Intermediate Layer)

In the present embodiment, an intermediate layer may be provided between the thermally expandable pressure-sensitive adhesive layer 60a and the supporting base 60b to improve the adhesion, the peeling property after heating, etc. (not shown in the drawings). Among these, a rubbery organic elastic intermediate layer is preferably provided as the intermediate layer. Accordingly, a rubbery organic elastic intermediate layer is provided to obtain a large adhesion area by making the surface of the thermally expandable pressure-sensitive adhesive layer 60a follow the shape of the surface of the semiconductor chip 53 well when adhering the semiconductor chip 53 to the temporary fixing material 60 (refer to FIG. 1(a)) and to expand the thermally expandable pressure-sensitive adhesive layer 60a uniformly and preferentially in the thickness direction by highly (precisely) controlling the heat expansion of the thermally expandable pressure-sensitive adhesive layer 60a when the sealed body 58 is heated and peeled from temporary fixing material 60.

The rubbery organic elastic intermediate layer can be provided on one surface or between the surfaces of the supporting base 60b.

For example, the rubbery organic elastic intermediate layer is preferably formed with natural rubber having a D-type shear D-type hardness based on ASTM D-2240 of 50 or less, especially 40 or less, synthetic rubber, or synthetic resin having rubber elasticity. Even if a material is essentially a hard polymer such as polyvinylchloride, dopants such as a plasticizer and a softener can be combined together to exhibit the rubber elasticity. Such compositions can be used as a constituting material of the rubbery organic elastic intermediate layer.

Examples of the method of forming the rubbery organic elastic intermediate layer include a method of coating a base with a coating liquid containing materials for forming a rubbery organic elastic layer such as the natural rubber, the synthetic rubber, and the synthetic resin having rubber elasticity (coating method); a method of adhering a base to a film containing the materials for forming a rubbery organic elastic layer or a laminated film in which a layer including the materials for forming a rubbery organic elastic layer is formed on one or more thermally expandable pressure-sensitive adhesive layers in advance (dry laminating method); and a method of coextruding a resin composition containing a constituting material of the base and a resin composition containing the materials for forming a rubbery organic elastic layer (coextruding method).

The rubbery organic elastic intermediate layer may be formed with a pressure-sensitive adhesive substance having natural rubber, synthetic rubber, or synthetic resin having rubber elasticity as a main component or may be formed with a foaming film, etc. having the main component. The foaming can be performed with a traditional method such as a method of mechanically stirring, a method of using gas produced by reaction, a method of using a foaming agent, a method of removing a soluble substance, a method of spraying, a method of forming syntactic foam, and a sintering method.

The thickness of the intermediate layer such as the rubbery organic elastic intermediate layer is 5 μm to 300 μm for example, and preferably about 20 μm to 150 μm. If, for example, the intermediate layer is a rubbery organic elastic intermediate layer and the thickness of the rubbery organic elastic intermediate layer is too small, a variation in the three-dimensional structure after heat foaming cannot be formed, and the peeling property may deteriorate.

The intermediate layer such as a rubbery organic elastic intermediate layer may be a single layer or a multiple layer having two or more layers.

The intermediate layer may contain various kinds of dopants (e.g. colorant, thickener, extender, filler, tackifier, plasticizer, anti-aging agent, antioxidant, surfactant, cross-linking agent, etc.) within the bounds of not impairing the effect of the temporary fixing material.

In the step of preparing a laminate, a plurality of the semiconductor chips 53 is arranged on the temporary fixing sheet 60 so that the circuit formation surface 53a of each of the semiconductor chips 53 faces the temporary fixing sheet 60 (refer to FIG. 1(a)). A known apparatus such as a flip-chip bonder and a die bonder can be used for the temporary fixing of the semiconductor chips 53.

The layout and the number of semiconductor chips 53 that are arranged can be appropriately set according to the shape and size of the temporary fixing sheet 60, the targeted production number of packages, etc. For example, the semiconductor chips 53 can be arranged in a matrix shape in which the semiconductor chips 53 are aligned in a plurality of rows and a plurality of columns. The shape and size of the laminate 50 (the temporary fixing sheet 60) in planar view are not particularly limited, and for example, the shape is a rectangle and the length of each side is 300 mm or more or the length of each side is 500 mm or more. One example of the step of preparing the laminate was shown above.

### [Step of Preparing Sheet for Sealing Electronic Component]

In the method for manufacturing an electronic component device according to the present embodiment, a sheet 40 for sealing an electronic component (also referred to as “a sealing sheet 40”) is prepared as shown in FIGS. 2(a) and 2(b) (Step B). The sealing sheet 40 may be prepared in a state where the sealing sheet 40 is laminated on a release liner 41 such as a polyethylene terephthalate (PET) film.

### (Sealing Sheet)

The probe tack force of the sealing sheet 40 at 25° C. in a probe tack test is 5 gf or less, preferably 3 gf or less, and more preferably 1 gf or less. The probe tack force of the sealing sheet 40 at 40° C. in a probe tack test is 10 gf or more, preferably 15 gf or more, and more preferably 20 gf or more. Because the probe tack force in a probe tack test is 5 gf or less at 25° C. and 10 gf or more at 40° C., it is possible to make the sheet for sealing an electronic component exhibit little adherability at a normal temperature of about 25° C. or lower (for example, about 15° C. to 25° C.) without cooling the sheet for sealing an electronic component to a low temperature (for example, about −10° C. to 5° C.). In addition, the temperature may be increased to about 40° C. or higher to make the sheet for sealing an electronic component exhibit adherability. Therefore, the steps C and D can be easily performed.

The probe tack test of the present invention is performed with the method described in the examples.

For example, the compounding ratios of the inorganic filler that is added and the amount of the organic component that exhibits adherability can be optimized to obtain the sealing sheet 40 having a probe tack force in a probe tack test of 5 gf or less at 25° C. and 10 gf or more at 40° C.

The minimum melt viscosity of the sealing sheet 40 at 40° C. to 150° C. is preferably 50 Pa·s to 20,000 Pa·s, more preferably 100 Pa·s to 15,000 Pa·s, and further preferably 200 Pa·s to 10,000 Pa·s. If the minimum melt viscosity of the sealing sheet 40 at 40° C. to 150° C. is 50 Pa·s or more, the resin constituting the sealing sheet 40 can be suppressed from protruding in the surface direction of the sealing sheet when forming a sealed body 58. If the minimum melt viscosity is 20,000 Pa·s or less, the semiconductor chips 53 can be suitably embedded.

The constituting materials of the sealing sheet 40 preferably include an epoxy resin and a phenol resin as a curing agent. Accordingly, good thermal curing properties can be obtained.

The epoxy resin is not especially limited. For example, various kinds of epoxy resins can be used such as a triphenylmethane-type epoxy resin, a cresol novolac-type epoxy resin, a biphenyl-type epoxy resin, a modified bisphenol A-type epoxy resin, a bisphenol A-type epoxy resin, a bisphenol F-type epoxy resin, a modified bisphenol F-type epoxy resin, a dicyclopentadiene-type epoxy resin, a phenol novolac-type epoxy resin, and a phenoxy resin. These epoxy resins may be used alone or in combination of two or more thereof.

From the viewpoint of securing the toughness of the epoxy resin after curing and the reactivity of the epoxy resin, epoxy resins are preferable which are solid at normal temperature and have an epoxy equivalent of 150 to 200 and a softening point or melting point of 50 to 130° C. Among these epoxy resins, a triphenylmethane-type epoxy resin, a cresol novolac-type epoxy resin, and a biphenyl-type epoxy resin are more preferable from the viewpoint of reliability.

The phenol resin is not especially limited as long as it initiates curing reaction with the epoxy resin. For example, there can be used a phenol novolac resin, a phenolaralkyl resin, a biphenylaralkyl resin, a dicyclopentadiene-type phenol resin, a cresol novolac resin, a resol resin, etc. These phenol resins may be used alone or in combination of two or more thereof.

From the viewpoint of the reactivity with the epoxy resin, phenol resins are preferably used which have a hydroxy group equivalent of 70 to 250 and a softening point of 50 to 110° C. Among these phenol resins, a phenol novolac resin is more preferably used from the viewpoint of its high curing reactivity. Further, phenol resins having low moisture absorbability can be also preferably used such as a phenolaralkyl resin and a bisphenylaralkyl resin from the viewpoint of reliability.

For the compounding ratio of the phenol resin to the epoxy resin, the epoxy resin and the phenol resin are preferably compounded so that the total amount of the hydroxy group in the phenol resin is 0.7 to 1.5 equivalents, and more preferably 0.9 to 1.2 equivalents, to 1 equivalent of the epoxy group in the epoxy resin.

The total content of the epoxy resin and the phenol resin in the sealing sheet 40 is preferably 2.5% by weight or more, and more preferably 3.0% by weight or more. If the content is 2.5% by weight or more, good adhering strength to the semiconductor chips 53 can be obtained. The total content of the epoxy resin and the phenol resin in the sealing sheet 40 is preferably 20% by weight or less, and more preferably 10% by weight or less. If the content is 20% by weight or less, moisture absorbability can be decreased.

The sealing sheet 40 preferably contains a thermoplastic resin. This makes it possible to provide a handling property when the sealing sheet 40 is uncured and low stress property to the cured product.

Examples of the thermoplastic resin include natural rubber, butyl rubber, isoprene rubber, chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6, 6-nylon, a phenoxy resin, an acrylic resin, saturated polyester resins such as PET and PBT, a polyamideimide resin, a fluororesin, and a styrene-isobutylene-styrene block copolymer. These thermoplastic resins may be used alone or in combination of two or more thereof. Among these, a styrene-isobutylene-styrene block copolymer is preferable from the viewpoint of its low stress property and low moisture absorption.

The content of the thermoplastic resin in the sealing sheet 40 is preferably 1.5% by weight or more, and more preferably 2.0% by weight. If the content is 1.5% by weight or more, the flexibility can be obtained. The content of the thermoplastic resin in the sealing sheet 40 is preferably 6% by weight or less, and more preferably 4% by weight or less. If the content is 4% by weight or less, the adhesion with the semiconductor chips 53 is good.

The sealing sheet 40 preferably contains an inorganic filler.

The inorganic filler is not especially limited, and various kinds of conventionally known fillers can be used. Examples thereof include powers of quartz glass, talc, silica (such as fused silica and crystalline silica), alumina, aluminum nitride, silicon nitride, and boron nitride. These may be used alone or in combination of two or more kinds. Among these, silica and alumina are preferable, and silica is more preferable due to the reason that the linear expansion coefficient can be satisfactorily decreased.

As silica, silica powers are preferable, and fused silica powers are more preferable. Examples of the fused silica powders include spherical fused silica powders and crushed and fused silica powders. However, spherical fused silica powders are preferable from the viewpoint of fluidity. Among these, powers having an average particle size of 10 to 30 μm are preferable, and powders having an average particle size of 15 to 25 μm are more preferable.

The average particle size can be obtained, for example, by measurement on a sample that is extracted arbitrarily from the population using a laser diffraction-scattering type particle size distribution measuring apparatus. Among these, silica powders are preferable having an average particle size of 10 μm to 30 μm, and more preferable having an average particle size of 15 μm to 25 μm.

For example, the average particle size can be measured by using a laser diffraction-scattering type particle size distribution measuring apparatus on a sample that is arbitrarily extracted from the population.

The content of the inorganic filler in the sealing sheet 40 is preferably 75% by weight to 95% by weight, and more preferably 78% by weight to 95% by weight relative to the total content of the sealing sheet 40. If the content of the inorganic filler is 75% by weight or more relative to the total content of the sealing sheet 40, the thermal expansion coefficient can be kept low, and thus mechanical damage due to thermal impact can be suppressed. On the other hand, if the content of the inorganic filler is 95% by weight or less relative to the total content of the sealing sheet 40, the flexibility, the fluidity, and the adhesion become more satisfactory.

The sealing sheet 40 preferably contains a curing accelerator.

The curing accelerator is not especially limited as long as it promotes curing of the epoxy resin and the phenol resin, and examples of the curing accelerator include organophosphate compounds such as triphenylphosphine and tetraphenylphosphonium tetraphenylborate; and imidazole compounds such as 2-phenyl-4,5-dihydroxymethylimidazole and 2-phenyl-4-methyl-5-hydroxymethylimidazole. Among these, 2-phenyl-4,5-dihydroxymethylimidazole is preferable due to the reason that the curing reaction does not rapidly proceed even when the temperature increases during kneading and the sealing sheet 40 can be produced satisfactorily.

The content of the curing accelerator is preferably 0.1 to 5 parts by weight to the total 100 parts by weight of the epoxy resin and the phenol resin.

The sealing sheet 40 preferably contains a flame retardant component. This makes it possible to reduce an expansion of combustion when the sealing sheet 40 catches fire due to short circuit of the parts or heat generation. Examples of the flame retardant component include various kinds of metal hydroxides such as aluminum hydroxide, magnesium hydroxide, iron hydroxide, calcium hydroxide, tin hydroxide, and composite metal hydroxide; and a phosphazene flame retardant.

From the viewpoint of exhibiting flame retardancy even with a small amount, the content of phosphorus element in the phosphazene flame retardant is preferably 12% by weight or more.

The content of the flame retardant component in the sealing sheet 40 is preferably 10% by weight or more, and more preferably 15% by weight or more in the entire organic component (excluding inorganic filler). If the content is 10% by weight or more, the flame retardancy can be obtained satisfactorily. The content of the thermoplastic resin in the sealing sheet 40 is preferably 30% by weight or less, and more preferably 25% by weight or less. If the content is 30% by weight or less, deterioration in the physical properties (deterioration in physical properties such as glass transition temperature and resin strength at high temperature) of the cured product tends to be suppressed.

The sealing sheet 40 preferably contains a silane coupling agent. The silane coupling agent is not especially limited, and an example includes 3-glycidoxypropyl trimethoxysilane.

The content of the silane coupling agent in the sealing sheet 40 is preferably 0.1 to 3% by weight. If the content is 0.1% by weight or more, the strength of the cured product is sufficiently made high, so that the water absorption can be lowered. If the content is 3% by weight or less, the amount of outgas can be decreased.

The sealing sheet 40 is preferably colored. With this configuration, the sealing sheet 40 can exhibit an excellent marking property and an excellent appearance, and a semiconductor device can be obtained having an appearance with added value. Because the colored sealing sheet 40 has an excellent marking property, various information such as character information and pattern information can be given by marking. Especially, the information such as character information and pattern information that is given by marking can be recognized visually with excellent visibility by controlling the color. It is possible to color-code the sealing sheet 40 by product, for example. When the sealing sheet 40 is colored (when it is not colorless or transparent), the color is not especially limited. However, the color is preferably a dark color such as black, blue, or red, and black is especially preferable.

In this embodiment, the dark color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of and b* are preferably −10 to 10, more preferably −5 to 5, and especially preferably −3 to 3 (above all, 0 or almost 0).

In this embodiment, L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

When the sealing sheet 40 is colored, a coloring material (colorant) is usable in accordance with a target color. The sheet of the present invention for sealing may be made of a single layer or made of plural layers. It is preferred that the colorant is added at least to the side of the sheet surface opposite to the sheet surface that faces the temporary fixing sheet. Specifically, when the sealing sheet is made of a single layer, the colorant may be evenly contained in the whole of the sealing sheet, or may be contained to be unevenly distributed in the side of the sheet surface opposite to the sheet surface that faces the temporary fixing sheet. When the sealing sheet is made of plural layers, it is permissible to add the colorant to a layer at the side of the sheet surface opposite to the sheet surface that faces the temporary fixing sheet, and further not to add the colorant to the other layer(s). In the present embodiment, a description will be made hereinafter about a case where the sheet of the present invention for sealing is the sealing sheet that is a sheet made of a single layer. When the colorant is added to the side of the sheet surface opposite to the sheet surface that faces the temporary fixing sheet in the sealing sheet, a region of the sheet which has been laser-marked can be improved in visibility. Various dark color materials such as black color materials, blue color materials, and red color materials can be suitably used, and especially the black color materials are suitable. The color materials may be any of pigments, dyes, and the like. The color materials can be used alone or two types or more can be used together. Any dyes such as acid dyes, reactive dyes, direct dyes, dispersive dyes, and cationic dyes can be used. The pigments are also not especially limited in the form, and may be appropriately selected from known pigments.

The use of, in particular, the dye as the coloring material puts the sealing sheet 40 into a state that the dye is evenly or substantially evenly dissolved or dispersed in the sheet 10, so that the sealing sheet 40 can easily be produced with an even or substantially even color density to be improved in markability and external appearance.

The black color material is not especially limited, and can be appropriately selected from inorganic black pigments and black dyes, for example. The black color material may be a color material mixture in which a cyan color material (blue-green color material), a magenta color material (red-purple color material), and a yellow color material are mixed together. The black color materials can be used alone or two types or more can be used together. The black color materials can be used also with other color materials other than black.

Specific examples of the black color materials include carbon black such as furnace black, channel black, acetylene black, thermal black, and lamp black, graphite (black lead), copper oxide, manganese dioxide, azo pigments such as azomethine azo black, aniline black, perylene black, titanium black, cyanine black, activated carbon, ferrite such as nonmagnetic ferrite and magnetic ferrite, magnetite, chromium oxide, iron oxide, molybdenum disulfide, chromium complex, complex oxide black, and anthraquinone organic black.

In the present invention, black dyes such as C. I. solvent black 3, 7, 22, 27, 29, 34, 43, and 70, C. I. direct black 17, 19, 22, 32, 38, 51, and 71, C. I. acid black 1, 2, 24, 26, 31, 48, 52, 107, 109, 110, 119, and 154, and C. I. disperse black 1, 3, 10, and 24; and black pigments such as C. I. pigment black 1 and 7 can be used as the black color material.

Examples of such black color materials that are available on the market include Oil Black BY, Oil Black BS, Oil Black HBB, Oil Black 803, Oil Black 860, Oil Black 5970, Oil Black 5906, and Oil Black 5905 manufactured by Orient Chemical Industries Co., Ltd.

Examples of color materials other than the black color materials include a cyan color material, a magenta color material, and a yellow color material. Examples of the cyan color material include cyan dyes such as C. I. solvent blue 25, 36, 60, 70, 93, and 95; and C. I. acid blue 6 and 45; and cyan pigments such as C. I. pigment blue 1, 2, 3, 15, 15:1, 15:2, 15:3, 15:4, 15:5, 15:6, 16, 17, 17:1, 18, 22, 25, 56, 60, 63, 65, and 66; C. I. vat blue 4 and 60; and C. I. pigment green 7.

Examples of the magenta color material include magenta dyes such as C. I. solvent red 1, 3, 8, 23, 24, 25, 27, 30, 49, 52, 58, 63, 81, 82, 83, 84, 100, 109, 111, 121, and 122; C. I. disperse red 9; C. I. solvent violet 8, 13, 14, 21, and 27; C. I. disperse violet 1; C. I. basic red 1, 2, 9, 12, 13, 14, 15, 17, 18, 22, 23, 24, 27, 29, 32, 34, 35, 36, 37, 38, 39, and 40; and C. I. basic violet 1, 3, 7, 10, 14, 15, 21, 25, 26, 27, and 28.

Examples of the magenta color material include magenta pigments such as C. I. pigment red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, and 245; C. I. pigment violet 3, 9, 19, 23, 31, 32, 33, 36, 38, 43, and 50; and C. I. vat red 1, 2, 10, 13, 15, 23, 29, and 35.

Examples of the yellow color material include yellow dyes such as C. I. solvent yellow 19, 44, 77, 79, 81, 82, 93, 98, 103, 104, 112, and 162; and yellow pigments such as C. I. pigment orange 31 and 43, C. I. pigment yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, and 195, and C. I. vat yellow 1, 3, and 20.

Various color materials such as cyan color materials, magenta color materials, and yellow color materials can be used alone or two types or more can be used together. When two types or more of various color materials such as cyan color materials, magenta color materials, and yellow color materials are used, the mixing ratio or the compounding ratio of these color materials is not especially limited, and can be appropriately selected according to the types of each color material and the intended color.

The light transmittance of the sealing sheet 40 to visible rays (wavelength: 380 to 800 nm) (visible light transmittance) is not particularly limited, and ranges, for example, preferably from 20 to 0%, more preferably from 10 to 0%, in particular preferably from 5 to 0%. When the visible light transmittance of the sealing sheet 40 is set to 20% or less, the sheet can be made good in printed-image visibility. Moreover, a bad effect of the passage of rays onto the semiconductor elements can be prevented.

About the visible light transmittance (%) of the sealing sheet 40, the sealing sheet 40 is produced with a thickness (average thickness) of 10 μm, and a product with a trade name “UV-2550” (manufactured by Shimadzu Corporation) is used to radiate visible rays having wavelengths of 380 to 800 nm at a predetermined intensity onto the sheet 10 (thickness: 10 μm) for sealing. The light intensity of the visible rays transmitted through the sealing sheet 40 by this radiation is measured, and then the visible light transmittance is calculated in accordance with the following expression.

Visible light transmittance (%)=(“light intensity of visible rays transmitted through sealing sheet 40”/“initial light intensity of visible rays”×100

This method for calculating the light transmittance (%) is applicable to the light transmittance (%) of the sealing sheet 40 when the sheet has any thickness other than 10 μm. Specifically, in accordance with Lambert-Beer's law, the absorbance A₁₀ thereof when the thickness is 10 μm can be calculated as follows:

A₁₀=α×L₁₀×C (1)

wherein L₁₀ represents the light path length; α, the absorption coefficient; and C, the concentration of the sample.

The absorbance A_{X} of the sample when the thickness thereof is X (μm) can be represented by the following expression (2).

A_{X}=α×L_{X}×C (2)

The absorbance A₂₀ when the thickness is 20 (μm) can be represented by the following expression (3):

A₁₀=−log₁₀ T₁₀ (3)

wherein T₁₀ represents the light transmittance when the thickness is 10 μm.

In accordance with the expressions (1) to (3), the absorbance A_{X} can be represented by the following.

$$\begin{matrix}{A}_{X} = {A}_{10} ( {L}_{X} \text{/} {L}_{10} ) \\ = - [ {log}_{10} ( {T}_{10} ) ] ( {L}_{X} \text{/} {L}_{10} )\end{matrix}$$

Using this absorbance, the light transmittance T_{X} (%) when the thickness is X (μm) can be calculated in accordance with the following:

T_{X}=10^{-AX}

wherein A_{X}=−[log₁₀(T₁₀)]× (L_{X}/L₁₀).

In the present embodiment, the thickness (average thickness) of the sealing sheet is 10 μm when the light transmittance (%) of the sealing sheet is gained. However, this thickness of the sealing sheet is merely a thickness used when the light transmittance (%) of the sealing sheet is gained. Thus, it is not meant that the thickness of the sealing sheet is 10 μm in the present invention.

The light transmittance (%) of the sealing sheet 40 is controllable in accordance with the kind and the content of the resin component, those of the colorant (such as the pigment or dye), those of the filler, and others.

Besides the above-mentioned individual components, any other additive may be appropriately blended into the sealing sheet 40, as required.

The thickness of the sealing sheet 40 is not particularly limited, and it is 50 μm to 2,000 μm for example, preferably 70 μm to 1,200 μm, and more preferably 100 μm to 700 μm from the viewpoint of using it as a sealing sheet and in which the semiconductor chip 53 can be suitably embedded in the embedding step (Step E).

The shape and size of the sealing sheet 40 in planar view are not particularly limited; however, they are preferably the shape and size including a region where the semiconductor chips 53 are arranged on the laminate 50 (refer to FIG. 1(a)). In addition, the shape and size are preferably about the same as the laminate 50. If the shape and size of the sealing sheet 40 include a region where the semiconductor chips 53 are arranged or the shape and size are about the same as the laminate 50, poor embedding of the semiconductor chips 53 can be suppressed. More specifically, the shape is a rectangle and the length of each side is 300 mm or more or the length of each side is 500 mm or more for example.

The method of manufacturing the sealing sheet 40 is not especially limited; however, preferred examples are a method of preparing a kneaded product of the resin composition for forming the sealing sheet 40 and applying the obtained kneaded product and a method of subjecting the obtained kneaded product to plastic-working to be formed into a sheet shape. This makes it possible to produce the sealing sheet 40 without using a solvent. Therefore, the effects on the semiconductor chip 53 from the volatilized solvent can be suppressed.

Specifically, each component described later is melted and kneaded with a known kneader such as a mixing roll, a pressure kneader, or an extruder to prepare a kneaded product, and the obtained kneaded product is applied or plastic-worked into a sheet shape. As a kneading condition, the temperature is preferably the softening point or higher of each component described above, and is for example 30 to 150° C. When the thermal curing property of the epoxy resin is considered, the temperature is preferably 40 to 140° C., and more preferably 60 to 120° C. The time is for example 1 to 30 minutes, and preferably 5 to 15 minutes.

The kneading is preferably performed under a reduced pressure condition (under reduced pressure atmosphere). This makes it possible to remove gas, and to prevent invasion of gas into the kneaded product. The pressure under the reduced pressure condition is preferably 0.1 kg/cm² or less, and more preferably 0.05 kg/cm² or less. The lower limit of the pressure under reduced pressure is not especially limited; however, it is 1×10⁻⁴ kg/cm² or more.

When the kneaded product is applied to form the sealing sheet 40, the kneaded product after being melt-kneaded is preferably applied while it is at high temperature without being cooled. The application method is not especially limited, and examples thereof include bar coating, knife coating, and slot-die coating. The application temperature is preferably the softening point or higher of each component described above. When the thermal curing property and molding property of the epoxy resin are considered, the temperature is for example 40 to 150° C., preferably 50 to 140° C., and more preferably 70 to 120° C.

When forming the sealing sheet 40 by plastic-working the kneaded product, the kneaded product after melt-kneaded is preferably subjected to plastic-working while it is at high temperature without being cooled. The plastic-working process is not especially limited, and examples thereof include flat plate pressing, T-die extrusion, screw-die extrusion, rolling, roll kneading, inflation extrusion, coextrusion, and calendar molding. The temperature for plastic-working is preferably the softening point or higher of each component described above. When the thermal curing property and molding property of the epoxy resin are considered, the temperature is for example 40 to 150° C., preferably 50 to 140° C., and more preferably 70 to 120° C.

The resin, etc. for forming the sealing sheet 40 can be dissolved and dispersed into an appropriate solvent to prepare varnish, and the varnish can be applied to obtain the sealing sheet 40.

### [Step of Arranging Sealing Sheet and Laminate]

After the step of preparing the sealing sheet, the sealing sheet 40 is arranged on the surface where the semiconductor chips 53 of the laminate 50 are temporarily fixed while arranging the laminate 50 on a lower heating plate 62 with the surface where the semiconductor chips 53 are temporarily fixed facing up as shown in FIGS. 3(a) and 3(b) (Step C). In this step, the laminate 50 may be arranged on the lower heating plate 62 first, and the sealing sheet 40 may be arranged on the laminate 50; or the sealing sheet 40 may be laminated on the laminate 50 first, and the laminated product in which the laminate 50 and the sealing sheet 40 are laminated may be arranged on the lower heating plate 62.

In the present embodiment, the step C is performed at 25° C. or lower. As described above, the probe tack force of the sealing sheet 40 in the probe tack test is 5 gf or less at 25° C. Therefore, the step C is performed at 25° C. or lower, so that the sealing sheet 40 can be made to exhibit little adherability. Therefore, even when the sealing sheet 40 is arranged (placed) in a condition where the positional displacement occurs in the step C as shown in FIG. 4 for example, the sealing sheet 40 can be easily rearranged to a correct position as shown in FIG. 3(b). Because the sealing sheet 40 has little adherability in the step C, various types of apparatus can be suppressed from being contaminated even when the sealing sheet 40 falls off, etc. due to trouble in apparatus, etc. The temperature when performing the step C is preferably 20° C. or lower and more preferably 15° C. or lower from a viewpoint of capability to make the adherability of the sealing sheet 40 lower as the temperature is lower.

In the present embodiment, the lower limit value of the temperature when performing the step C is not particularly limited, and for example, the lower limit value can be −10° C. or lower. Especially, because excessive cooling may complicate the step, the temperature can be made 0° C. or higher for example.

### [Step of Temporarily Fixing Sheet for Sealing Electronic Component to Semiconductor Chips]

Next, the temperature of the sealing sheet 40 in a state where the sealing sheet 40 is arranged on the semiconductor chips 53 (refer to FIG. 3(a)) to 40° C. or higher to temporarily fix the sealing sheet 40 to the semiconductor chips 53 (Step D). As described above, the probe tack of the sealing sheet 40 in the probe tack test is 10 gf or more at 40° C. Therefore, the temperature of the sealing sheet 40 is increased to 40° C. or higher in the step D to make the sealing sheet 40 exhibit the adherability after the alignment is completed in the step C, and the sealing sheet 40 can be fixed (temporarily fixed) on the semiconductor chips 53. The increased temperature in the step D is preferably 50° C. or higher, and more preferably 60° C. or higher from a viewpoint of capability to make the adherability of the sealing sheet 40 higher as the temperature is higher.

In the present embodiment, the upper limit of the increased temperature in the step D is not particularly limited, and for example, the upper limit can be 100° C. or lower. However, the increased temperature can be 90° C. or lower for example from a viewpoint of the heat resistance of the sealing sheet 40, etc.

The method of increasing the temperature of the sealing sheet 40 is not particularly limited, and examples include a method of increasing the temperatures of both or any one of the lower heating plate 62 and an upper heating plate 64, a method of increasing the temperature of the sealing sheet 40 in an oven, and a method of blowing hot air from a dryer to increase the temperature of the sealing sheet 40. In the present embodiment, the method is preferable of increasing the temperatures of both or any one of the lower heating plate 62 and the upper heating plate 64 from a viewpoint of simplifying the step.

### [Step of Forming Sealed Body]

Next, the semiconductor chips 53 are embedded in the sealing sheet 40 by heat pressing with the lower heating plate 62 and upper heating plate 64 as shown in FIG. 5 to form the sealed body 58 in which the semiconductor chips 53 are embedded in the sealing sheet 40 (Step E). As a result, the sealing sheet 40 functions as a sealing resin for protecting the semiconductor chips 53 and other associated components from the external environment. Accordingly, the sealed body 28 can be obtained in which the semiconductor chips 53 temporarily fixed on the temporary fixing material 60 are embedded in the sealing sheet 40. Because no positional displacement occurs between the sealing sheet 40 and the semiconductor chips 53, the yield of the electronic component device manufactured from the sealed body 58 becomes satisfactory.

The heat-pressing conditions when embedding the semiconductor chips 53 in the sealing sheet 40 are preferably conditions so that the semiconductor chips 53 can be suitably embedded in the sealing sheet 40. The temperature is 40° C. to 150° C. for example, and preferably 60° C. to 120° C.; the pressure is 0.1 MPa to 10 MPa, and preferably 0.5 MPa to 8 MPa; and the time is 0.3 minute to 10 minutes, and preferably 0.5 minute to 5 minutes. Accordingly, an electronic component device can be obtained in which the semiconductor chips 53 are embedded in the sealing sheet 40. Further, the semiconductor chips 53 and the sealing sheet 40 are preferably pressed together under reduced pressure conditions in consideration of improving the tackiness and the followability of the sealing sheet 40 to the semiconductor chips 53 and the temporary fixing material 60.

As the reduced pressure conditions, the pressure is 0.1 kPa to 5 kPa, and preferably 0.1 Pa to 100 Pa; and the reduced pressure holding time (from a time when the pressure is reduced to a time when the pressing is started) is 5 seconds to 600 seconds for example, and preferably 10 seconds to 300 seconds.

### [Step of Peeling Release Liner]

Next, a release liner 41 is peeled (refer to FIG. 6).

### [Thermal Curing Step]

Next, the sealing sheet 40 is thermally cured. Specifically, for example, the entire sealed body 58 is heated in which the semiconductor chips 53 temporarily fixed on the temporary fixing material 60 are embedded in the sealing sheet 40.

As the conditions of the thermal curing treatment, the heating temperature is preferably 100° C. or higher, and more preferably 120° C. or higher. On the other hand, the upper limit of the heating temperature is preferably 200° C. or lower, and more preferably 180° C. or lower. The heating time is preferably 10 minutes or more, and more preferably 30 minutes or more. On the other hand, the upper limit of the heating time is preferably 180 minutes or less, and more preferably 120 minutes or less. A pressure may be applied as necessary; the pressure is preferably 0.1 MPa or more, and more preferably 0.5 MPa or more. On the other hand, the upper limit thereof is preferably 10 MPa or less, and more preferably 5 MPa or less.

### [Step of Peeling Thermally Expandable Pressure-Sensitive Adhesive Layer]

Next, the thermally expandable pressure-sensitive adhesive layer 60a is thermally expanded by heating the temporary fixing material 60 to perform peeling between the thermally expandable pressure-sensitive adhesive layer 60a and the sealed body 58 as shown in FIG. 7. A procedure can be also suitably adopted in which the peeling is performed at the interface between the supporting base 60b and the thermally expandable pressure-sensitive adhesive layer 60a, and the peeling by thermal expansion is performed at the interface of the thermally expandable pressure-sensitive adhesive layer 60a and the sealed body 58. In both cases, the thermally expandable pressure-sensitive adhesive layer 60a is heated and thermally expanded to decrease its adhering strength, which makes the peeling at the interface between the thermally expandable pressure-sensitive adhesive layer 60a and the sealed body 58 easy. The conditions described in the section of “Method of thermally expanding thermally expandable pressure-sensitive adhesive layer” can be suitably adopted as the conditions of thermal expansion. Particularly, the thermally expandable pressure-sensitive adhesive layer preferably has a configuration with which the layer is peeled by heating in the step of peeling the thermally expandable pressure-sensitive adhesive layer without being peeled by heating in the thermal curing step.

### [Step of Grinding Sealing Sheet]

Next, the sealing sheet 40 of the sealed body 58 may be grinded as necessary to expose the backside 53c of the semiconductor chip 53 as shown in FIG. 8. The method of grinding the sealing sheet 11 is not particularly limited, and an example includes a method of grinding the sealing sheet 40 using a grinding wheel rotating at high speed.

### (Step of Forming Rewiring)

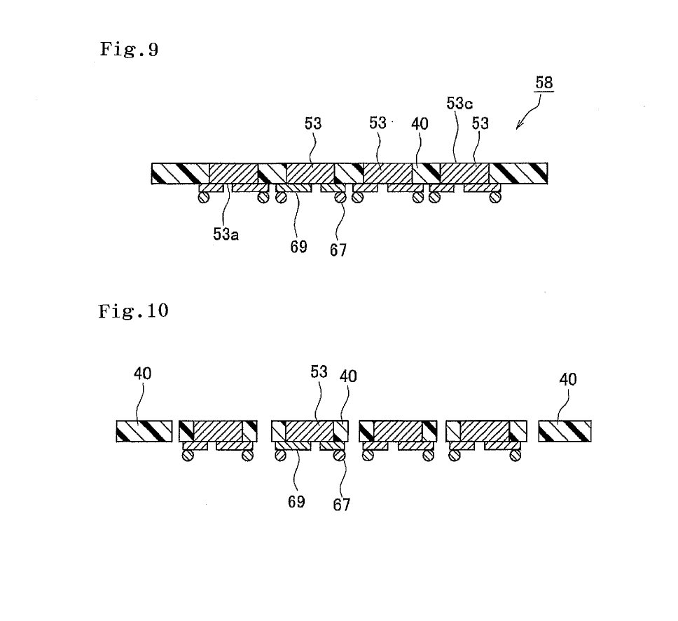

The present embodiment preferably further includes a step of forming a rewiring for forming a rewiring 69 on the circuit formation surface 53a of the semiconductor chip 53 of the sealed body 58. In the step of forming a rewiring, the temporary fixing material 60 is peeled to form the rewiring 69 connecting to the exposed semiconductor chip 53 on the sealed body 58 (refer to FIG. 9).

For example, a metal seed layer is formed on the exposed semiconductor chip 53 with the known method such as a vacuum deposition method, and the rewiring 69 can be formed with the known method such as a semiadditive method.

Then, an insulation layer such as polyimide and PBO may be formed on the rewiring 69 and the sealed body 58.

### (Step of Forming Bump)

Next, a bumping process may be performed to form a bump 67 on the formed rewiring 69 (refer to FIG. 9). The bumping process can be performed with the known method such as solder ball formation and solder plating.

### (Dicing Step)

Finally, the laminate is diced including the components such as the semiconductor chip 53, the sealing sheet 40, and the rewiring 69 (refer to FIG. 10). Accordingly, a semiconductor device 59 can be obtained in which the wiring is lead out to the outside of the chip region.

In the above-described embodiment, the case was explained in which the sealing sheet 40 is prepared having a probe tack force in a probe tack test of 5 gf or less at 25° C. and 10 gf or more at 40° C. (Step B), the sealing sheet 53 is arranged on the semiconductor chips 53 at 25° C. or lower (Step C), and the temperature of the sealing sheet 40 in a state where the sealing sheet 40 is arranged on the semiconductor chips 53 to 40° C. or higher and the sealing sheet 40 is temporarily fixed to the semiconductor chips 53 (Step D).

However, the sealing sheet 40 having a probe tack force in a probe tack test of 5 gf or less at 25° C. and 10 gf or more at 40° C. may not be used in the method for manufacturing an electronic component device according to the present invention.

For example, a sheet for sealing an electronic component having a probe tack force of 10 gf or more at room temperature (for example, about 10° C. to 35° C.), that is, a sheet for sealing an electronic component having adherability of a certain degree at room temperature may be used as the sheet for sealing an electronic component. In the case, the step C is performed under a temperature condition in which the sheet for sealing an electronic component exhibits little adherability, that is, a condition in which the probe tack force of the sheet for sealing an electronic component in a probe tack test is 5 gf or less (for example, about −10° C. to 5° C.); and the step D is performed by increasing the temperature of the sheet for sealing an electronic component (for example, increasing the temperature by heating or naturally increasing the temperature). Specifically, the sheet for sealing an electronic component is refrigerated or frozen in advance, and the step C is performed in this state; and after the step C is completed, the temperature of the sheet for sealing an electronic component may be increased to room temperature. Even with this method, the alignment of the sheet for sealing an electronic component can be easily performed; and after the alignment, the fixing (temporary fixing) can be performed.

For example, constituting materials that are the same as the sealing sheet 40 explained above can be used, and the compounding amount of each constituting material can be appropriately adjusted to obtain the sheet for sealing an electronic component having a probe tack force of 10 gf or more at room temperature (for example, about 10° C. to 35° C.). A conventionally known sheet for sealing an electronic component can be also adopted.

Only the step A, the step B, the step C, the step D, and the step E have to be performed in the present invention. Other steps are optional, and they may be performed or may not be performed.

The case was explained in the embodiment described above in which “the support” of the present invention is the temporary fixing material 60. However, “the laminate” of the present invention is not limited to this example, and the laminate may be a laminate in which the semiconductor chips are fixed on a support having strength of a certain degree. Another example of “the laminate” of the present invention is “a laminate in which the semiconductor chips are flip-chip bonded to the circuit formation surface of a semiconductor wafer”.

In the embodiment described above, the case was explained in which “the electronic component” of the present invention is the semiconductor chip 53. However, “the electronic component” of the present invention is not limited to this example. Examples of the electronic component of the present invention include an electronic device having a hollow structure (hollow-type electronic device) such as a sensor, MEMS (Micro Electro Mechanical Systems), and a SAW (Surface Acoustic Wave) filter; a semiconductor element such as a semiconductor chip, an IC (integrated circuit), and a transistor; a capacitor; and a resistor. The hollow structure is a structure in which there is a hollow space between an electronic device and a substrate where the electronic device is mounted.

### EXAMPLES

The preferred working examples of this invention will be explained in detail below. However, the working examples are not intended to be limited thereto in the scope of this invention. In addition, any of “parts” in each working example is on a weight base unless otherwise specified.

The components used in the examples will be explained.

Epoxy resin: Bisphenol F epoxy resin, epoxy equivalent weight 200 g/eq, softening point 80° C. (trade name “YSLV-80XY” manufactured by Nippon Steel Chemical Co., Ltd.)

Phenol resin A: Phenol resin having a bisphenylaralkyl skeleton, hydroxyl equivalent weight 203 g/eq, softening point 67° C. (trade name “MEH-7851-SS” manufactured by Meiwa plastic Industries, Ltd.)

Phenol resin B: Phenol novolak resin, hydroxyl equivalent weight 107 g/eq, softening point 60° C. (trade name “ND564” manufactured by Showa Highpolymer Co., Ltd.)

Thermoplastic resin: MBS resin, primary particle size 0.5 μm (trade name “METABLEN J-5800” manufactured by Mitsubishi Rayon Co., Ltd.)

Inorganic filler: Fused spherical silica, average particle size 20 μm (trade name “FB-9454FC” manufactured by Denka Co., Ltd.)

Carbon black: trade name “#20” manufactured by Mitsubishi Chemical Corporation

Curing accelerator: 2-phenyl-4,5-dihydroxymethylimidazole (trade name “2PHZ-PW” manufactured by Shikoku Chemicals Corporation)

### EXAMPLES AND COMPARATIVE EXAMPLE

### Examples 1 to 3 and Comparative Example 1

Each of the components was compounded according to the compounding ratio described in Table 1, and the compound was melted and kneaded at 60° C. to 120° C. for 10 minutes under a reduced pressure condition (0.01 kg/cm²) using a roll kneader to prepare a kneaded product. Next, the obtained kneaded product was arranged so as to be sandwiched by two cover films of 50 μm (trade name “MRF” manufactured by Mitsubishi Plastics, Inc.), and formed into a sheet with a flat plate press method to produce a sealing sheet having a thickness of 200 μm.

### Example 4

According to the compounding ratios described in Table 1, the epoxy resin, the phenol resin, the thermoplastic resin, and the inorganic filler were added in an organic solvent MEK (methylethylketone) so that the solid content concentration was 95%, and the mixture was stirred. The stirring was performed at 800 rpm rotation for 5 minutes using a planetary centrifugal mixer (manufactured by Thinky Corporation). According to the compounding ratios described in Table 1, the carbon black and the curing accelerator were also added in the mixture, MEK was added so that the solid content concentration was 90%, and the mixture was stirred further at 800 rpm for 3 minutes to obtain an application liquid.

The application liquid was applied onto a silicone release-treated polyethylene terephthalate film having a thickness of 50 μm, and the film was dried at 120° C. for 3 minutes to produce a resin sheet having a thickness of 100 μm. The produced resin sheets were pasted together at 90° C. using a roll laminator to produce a sealing sheet having a thickness of 500 μm.

### [Measurement of Probe Tack Force]

Two plates of 8 mmφ (diameter 8 mm, stainless steel (SUS)) were loaded in a viscoelasticity measuring apparatus (trade name “RSA-3” manufactured by TA Instruments). The sealing sheet was fixed to the lower plate of these two plates with a double sided tape, and the top plate (probe) was lowered in an atmosphere of 25° C. to press the upper plate onto the sealing sheet with a load of 100 g for 1 second. Then, the upper plate was raised to measure a load that is necessary to peel the upper plate from the sealing sheet.

The same measurement was performed also in an atmosphere of 40° C.

The results are shown in Table 1.

### [Evaluation of Reworkability]

The sealing sheet (size 65 mm square, thickness 200 μm) was placed on an alumina substrate (size 70 mm square, thickness 0.25 mm) at room temperature (25° C.) for 1 minute, and the edge of the sealing sheet was held by tweezers to be lifted. The case in which only the sealing sheet was lifted was marked as ◯, and the case in which the substrate was lifted with the resin sheet by sticking was marked as x. The results are shown in Table 1.

### [Evaluation of Positional Displacement]

The sealing sheet (size 65 mm square, thickness 200 μm) was placed on an alumina substrate (size 70 mm square, thickness 0.25 mm), the sheet was left on a hot plate of 40° C. at rest for 5 minutes, and the alumina substrate and the sealing sheet was placed in a vacuum packaging container (aluminum three-sided bag for retort, white, HA-1013H, size 100 mm×130 mm) to be vacuum-packed in conditions of 90° C. and 1 Torr. The alumina substrate and the sealing sheet were heated with the vacuum packaging container at 150° C. for 1 hour to cure the sealing sheet. The vacuum packaging container was cooled to room temperature, the laminated product consisting of the alumina substrate and the cured sealing sheet was taken out from the vacuum packaging container, and whether or not the cured sealing sheet deviated from its initial position was confirmed. The positional displacements of 30 laminates were confirmed, and the number of the laminates in which the positional displacement occurred was counted.

The case in which the ratio representing with ((the number of laminates in which positional displacement occurred/30 laminates)×100) was 10% or less was marked as ◯, and the case in which the ratio represented therewith exceeded 10% was marked as x. The results are shown in Table 1.

TABLE 1

| | | | | | | Comparative |
|---|---|---|---|---|---|---|
| | | Example 1 | Example 2 | Example 3 | Example 4 | Example 1 |
| Compounding Ratio | Epoxy Resin | 4.5 | 3.5 | 3 | 3 | 4.3 |
| (Parts by Weight) | Phenol Resin A | 0.7 | 1 | 1.1 | 1.1 | 1.6 |
| | Phenol Resin B | 2.2 | 1.6 | 1.1 | 1.1 | 1.6 |
| | Thermoplastic Resin | 3.3 | 2.6 | 2.5 | 2.5 | 3.3 |
| | Inorganic Filler | 90 | 91 | 92 | 92 | 89 |
| | Carbon Black | 0.2 | 0.2 | 0.2 | 0.2 | 0.2 |
| | Curing Accelerator | 0.1 | 0.1 | 0.1 | 0.1 | 0.1 |
| | Total | 100 | 100 | 100 | 100 | 100 |
| Evaluation | Probe Tack Force [gf] at 25° C. | 4 | 2 | 0 | 1 | 25 |
| | Probe Tack Force [gf] at 40° C. | 500 | 50 | 10 | 12 | 1000 |
| | Reworkability | ∘ | ∘ | ∘ | ∘ | x |
| | Positional Displacement | ∘ | ∘ | ∘ | ∘ | ∘ |

### DESCRIPTION OF REFERENCE SIGNS

40 Sheet for Sealing Electronic Component (Sealing Sheet)
50 Laminate
53 Semiconductor Chip
58 Sealed Body
59 Semiconductor Device
60 Temporary Fixing Material

1. A method for manufacturing an electronic component device, comprising:
a step A of preparing a laminate in which electronic components are fixed on a support,
a step B of preparing a sheet for sealing an electronic component,
a step C of arranging the sheet for sealing an electronic component on the electronic components under a condition in which the probe tack force of the sheet for sealing an electronic component in a probe tack test is 5 gf or less,
a step D of increasing a temperature of the sheet for sealing an electronic component in a state where the sheet for sealing an electronic component is arranged on the electronic components until the probe tack force of the sheet for sealing an electronic component in a probe tack test becomes 10 gf or more and temporarily fixing the sheet for sealing an electronic component to the electronic components, and
a step E of embedding the electronic components in the sheet for sealing an electronic component to forma sealed body in which the electronic components are embedded in the sheet for sealing an electronic component.

2. The method for manufacturing an electronic component device according to claim 1, wherein the probe tack force of the sheet for sealing an electronic component in a probe tack test is 5 gf or less at 25° C., and 10 gf or more at 40° C.

3. The method for manufacturing an electronic component device according to claim 2, wherein
the step C is a step of arranging the sheet for sealing an electronic component on the electronic components at 25° C. or lower, and
the step D is a step of increasing a temperature of the sheet for sealing an electronic component to 40° C. or higher and temporarily fixing the sheet for sealing an electronic component to the electronic components.

4. A sheet for sealing an electronic component having a probe tack force in a probe tack test of 5 gf or less at 25° C. and 10 gf or more at 40° C.
